(19) United States
(12) Patent Application Publication
(10) Pub. No.: US 2025/0258203 A1
(43) Pub. Date: Aug. 14, 2025

(54) VOLTAGE DETECTOR

(71) Applicant: ABLIC Inc., Nagano (JP)

(72) Inventors: Hironori YANO, Nagano (JP); Fumiyasu UTSUNOMIYA, Nagano (JP)

(73) Assignee: ABLIC Inc., Nagano (JP)

(21) Appl. No.: 19/012,832

(22) Filed: Jan. 7, 2025

(30) Foreign Application Priority Data
Feb. 13, 2024 (JP) 2024-019736

(51) Int. Cl. G01R 19/00

(52) U.S. Cl. CPC G01R 19/0084

(57) ABSTRACT

A voltage detector includes a voltage detection circuit including: a first current mirror circuit into which a current of a first current source composed of a depletion-type MOS transistor, is input; an enhancement-type first MOS transistor having a gate connected to an input port a drain connected to an output port and the first current mirror circuit; and a switch circuit controlled by an enable signal received by a control port; and a start-up circuit including: a current detection circuit that outputs the enable signal upon detecting that an output current of a second current mirror circuit, into which a current of a second current source is input, has become equal to or greater than a predetermined current. The voltage detection circuit outputs a detection signal corresponding to a voltage of the input port from the output port in response to receiving the enable signal at the switch circuit.

### CROSS-REFERENCE TO RELATED APPLICATION

This application claims the priority benefits of Japanese application no. 2024-019736, filed on Feb. 13, 2024. The entirety of the above-mentioned patent application is hereby incorporated by reference herein and made a part of this specification.

### BACKGROUND

### Technical Field

The present invention relates to a voltage detector.

### Related Art

FIG. 3 illustrates an example configuration of a conventional voltage detector.

The voltage detector in FIG. 3 includes a depletion-type N-Metal-Oxide-Semiconductor (NMOS) transistor 51 as a current source and an enhancement-type NMOS transistor 52.

The NMOS transistor 51, which operates as a constant current source, has its drain connected to a power supply port, and its gate and source connected to a drain of the NMOS transistor 52. The NMOS transistor 52 has its gate connected to an input port, its source connected to a ground port, and its drain connected to an output port.

In the case that a voltage VIN input to the input port is low and the NMOS transistor 52 is off, a detection signal DET output from the output port is at a High level. As the voltage VIN increases, a detection signal DET changes from High level to Low level. The voltage VIN at this point is called the detection voltage of the voltage detector. The detection voltage may be expressed as Vt₅₂+|Vt₅₁|, in the case that the threshold voltage of the NMOS transistor 52 is Vt₅₂ and the threshold voltage of the NMOS transistor 51 is Vt₅₁.

In the conventional voltage detector configured as described above, it is possible to make the temperature characteristics of the detection voltage almost flat by making the NMOS transistor 51 and the NMOS transistor 52 to have approximately the same aspect ratio (W length/L length).

### SUMMARY

### Technical Problem

In the conventional voltage detector, in the case that the NMOS transistor 51 and the NMOS transistor 52 have approximately the same aspect ratio, a minimum operating power supply voltage of the voltage detector becomes |Vt₅₁|×2. For example, in a case where |Vt₅₁| is about 0.2V at room temperature, it becomes about 0.3V at a high temperature of 85° C. As a result, the minimum operating power supply voltage of the conventional voltage detector becomes about 0.6V at a high temperature of 85° C.

In the case where a power supply voltage is lower than the minimum operating power supply voltage, there has been an issue that the detection signal DET becomes Low level even when the voltage VIN is lower than the desired detection voltage, because the NMOS transistor 51 operates in the non-saturation region.

The present invention provides a voltage detector that has flat temperature characteristics of the detection voltage while having a low minimum operating power supply voltage, and erroneous detection is prevented below the minimum operating power supply voltage.

### Solution to Problem

A voltage detector according to an embodiment of the present invention includes a voltage detection circuit and a start-up circuit. The voltage detection circuit includes: a first current source, with one end connected to a first power supply port and including a depletion-type MOS transistor, a first current mirror circuit, with an input port connected to the other end of the first current source and into which a current of the first current source is input, an enhancement-type first MOS transistor, with a gate connected to an input port, a drain connected to an output port and an output port of the first current mirror circuit, and into which an output current of the first current mirror circuit is input, and a switch circuit, controlled by an enable signal received by a control port. The start-up circuit includes: a second current source, a second current mirror circuit, into which a current of the second current source is input, and a current detection circuit, outputting the enable signal indicating enable in response to detecting that an output current of the second current mirror circuit is input and that the output current has become equal to or greater than a predetermined current. The voltage detection circuit outputs a detection signal corresponding to a voltage of the input port from the output port in response to receiving the enable signal indicating enable from the start-up circuit at the switch circuit.

### Effects

According to the present invention, it is possible to provide a voltage detector in which, since a constant current source of a voltage detection circuit is composed of a depletion-type MOS transistor and a current mirror circuit, and a start-up circuit is provided for detecting that a power supply voltage has become equal to or higher than a minimum operating power supply voltage of the voltage detection circuit, the temperature characteristics of the detection voltage is flat while the minimum operating power supply voltage is low, and erroneous detection is prevented below the minimum operating power supply voltage.

### BRIEF DESCRIPTION OF THE DRAWINGS

FIG. 1 is a circuit diagram illustrating an example of a voltage detector according to an embodiment of the present invention.

FIG. 2 is a circuit diagram illustrating another example of a voltage detector according to the present embodiment.

FIG. 3 is a circuit diagram illustrating a conventional voltage detector.

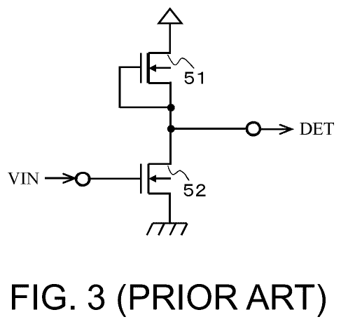

### DESCRIPTION OF THE EMBODIMENTS

The following describes a voltage detector 1 according to an embodiment of the present invention based on the drawings.

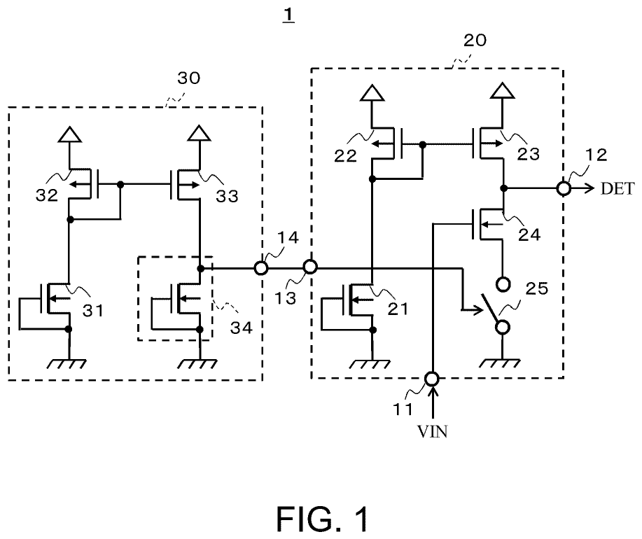

FIG. 1 is a circuit diagram of the voltage detector 1 according to the present embodiment.

The voltage detector 1 includes a voltage detection circuit 20 and a start-up circuit 30. In the case that the start-up circuit 30 outputs a signal indicating enable, the voltage detector 1 outputs, as a detection signal DET, a signal output by the voltage detection circuit 20 in response to the input voltage VIN. In the example of this embodiment, in the case that the input voltage VIN becomes equal to or higher than the detection voltage, the detection signal DET becomes Low level.

The voltage detection circuit 20 includes a depletion-type NMOS transistor 21 serving as a current source, enhancement-type P-Metal-Oxide-Semiconductor (PMOS) transistors 22 and 23 constituting a current mirror circuit, an enhancement-type NMOS transistor 24, a switch circuit 25, an input port 11, an output port 12, and a control port 13.

The NMOS transistor 21 has its source and gate connected to the ground port, and its drain connected to the input port of the current mirror circuit. The PMOS transistor 22 and the PMOS transistor 23 constitute the current mirror circuit. The NMOS transistor 24 has its drain connected to the output port 12 and the output port of the current mirror circuit, and its gate connected to the input port 11. The switch circuit 25, which is controlled by an enable signal EN received from the control port 13, is connected, for example, between the source of the NMOS transistor 24 and the ground port.

The start-up circuit 30 includes a depletion-type NMOS transistor 31 serving as a current source, enhancement-type PMOS transistors 32 and 33 constituting a current mirror circuit, a current detection circuit 34, and an output port 14. The current detection circuit 34 is composed of, for example, a depletion-type NMOS transistor with its gate and source connected.

The NMOS transistor 31 has its source and gate connected to the ground port, and its drain connected to the input port of the current mirror circuit. The PMOS transistor 32 and the PMOS transistor 33 constitute the current mirror circuit. The current detection circuit 34 is connected between the output port of the current mirror circuit and the ground port, and its output port is connected to the output port 14.

The operation of the voltage detector 1 will be described next.

First, the operation of the voltage detection circuit 20 will be described.

In the case that the start-up circuit 30 outputs a signal indicating enable, the voltage detection circuit 20 switches, in response to the voltage VIN at the input port 11 becoming equal to or higher than the detection voltage, the signal output from the output port 12 is switched from a High level (for example, power supply port voltage) to a Low level (for example, ground port voltage).

The NMOS transistor 21 is a current source and generates a first reference current. The current mirror circuit composed of PMOS transistors 22 and 23 generates and outputs a second reference current from the input first reference current. The switch circuit 25 is controlled by the enable signal EN received by the control port 13, turning on in response to a High level enable signal EN indicating enable, and turning off in response to a Low level indicating disable. In the case that the switch circuit 25 is ON, the NMOS transistor 24 has the second reference current corresponding to the first reference current output by the current mirror circuit input to its drain. The detection voltage of the voltage detection circuit 20 becomes the gate voltage when the second reference current flows between the drain and source of the NMOS transistor 24. In the case where the first reference current and the second reference current are equal, and the aspect ratios of the NMOS transistor 21 and the NMOS transistor 24 are the same, when the threshold voltage of the NMOS transistor 21 is set as Vt₂₁ and the threshold voltage of the NMOS transistor 24 is set as Vt₂₄, the detection voltage may be expressed as Vt₂₄+/Vt₂₁|. The temperature characteristics of the detection voltage may be made nearly flat by setting the aspect ratios (W length/L length) of the NMOS transistor 21 and the NMOS transistor 24 to be almost the same.

The minimum operating power supply voltage of the voltage detection circuit 20 will be described.

For the first reference current to be a predetermined current, both the NMOS transistor 21 and the PMOS transistor 22 need to operate in the saturation region. The power supply voltage for both the NMOS transistor 21 and the PMOS transistor 22 to operate in the saturation region is Vov₂₂+|Vt₂₂|+|Vt₂₁| or higher. Vt₂₁ is the threshold voltage of the NMOS transistor 21, Vt₂₂ is the threshold voltage of the PMOS transistor 22, and Vov₂₂ is the overdrive voltage at which the PMOS transistor 22 may cause the first reference current to flow. In other words, this power supply voltage is the minimum operating power supply voltage of the voltage detection circuit 20.

Here, regarding the first reference current, the current flowing through the NMOS transistor 21 is set to be small, and the driving capability of the PMOS transistor 22 is set to be large. By setting it this way, Vov₂₂ becomes a negligibly small value compared to |Vt₂₂| or |Vt₂₁|. Thus, the minimum operating power supply voltage of the voltage detection circuit 20 becomes |Vt₂₂|+|Vt₂₁|. Since |Vt₂₂| has a negative temperature characteristic and |Vt₂₁| has a positive temperature characteristic, the minimum operating power supply voltage of the voltage detection circuit 20 has little variation with respect to temperature. For example, at room temperature, |Vt₂₂| is set to 0.2V and |Vt₂₁| is set to 0.2V. The minimum operating power supply voltage at room temperature becomes 0.4V, but the minimum operating power supply voltage at a high temperature of 85° C. also becomes 0.4V because |Vt₂₂| and |Vt₂₁| cancel out their changes with respect to temperature.

Thus, the voltage detector 1 of the present invention can suppress the increase in the minimum operating power supply voltage at high temperatures, and can thus reduce the minimum operating power supply voltage.

Next, the operation of the start-up circuit 30 will be described.

The NMOS transistor 31 is a current source and outputs the third reference current. The current mirror circuit composed of PMOS transistors 32 and 33 outputs a fourth reference current based on the input third reference current. The start-up circuit 30 outputs a High level enable signal EN from the output port to the output port 14 in response to the current detection circuit 34 detecting that the fourth reference current has become equal to or greater than a predetermined current. For example, the aspect ratio of the NMOS transistor constituting the current detection circuit 34 may be set slightly smaller than that of the NMOS transistor 31.

The minimum operating power supply voltage of the start-up circuit 30 will be described.

For the third reference current to become a predetermined current, both the NMOS transistor 31 and the PMOS transistor 32 need to operate in the saturation region. The power supply voltage for both the NMOS transistor 31 and the PMOS transistor 32 to operate in the saturation region is Vov₃₂+|Vt₃₂|+|Vt₃₁| or higher. Vt₃₁ is the threshold voltage of the NMOS transistor 31, Vt₃₂ is the threshold voltage of the PMOS transistor 32, and Vov₃₂ is the overdrive voltage of the PMOS transistor 32 required for causing the third reference current to flow. In other words, this power supply voltage is the minimum operating power supply voltage of the start-up circuit 30. Moreover, in case of below the minimum operating power supply voltage, the output port 14 is pulled down to Low level by the current detection circuit 34.

Here, regarding the third reference current, the current flowing through the NMOS transistor 31 is set to be small, and the driving capability of the PMOS transistor 32 is set to be large. By setting it this way, Vov₃₂ becomes a negligibly small value compared to |Vt₃₂| or |Vt₃₁|. Thus, the minimum operating power supply voltage of the start-up circuit 30 becomes |Vt₃₂|+/Vt₃₁|. In other words, similar to the voltage detection circuit 20, the increase in the minimum operating power supply voltage at high temperatures can be suppressed, and thus the minimum operating power supply voltage can be reduced.

Next, an example of the relationship between the voltage detection circuit 20 and the start-up circuit 30 will be described.

The third reference current of the start-up circuit 30 is set equal to the first reference current of the voltage detection circuit 20. The PMOS transistor 22 and PMOS transistor 23 of the voltage detection circuit 20 are set to have an aspect ratio of 1 (for example, W=10 μm, L=10 μm). The PMOS transistor 32 and PMOS transistor 33 of the start-up circuit 30 are set to have an aspect ratio of 0.8 (for example, W=8 μm, L=10 μm).

In order for a predetermined current to flow, the current mirror circuit requires that MOS transistors operate in the saturation region, and thus the smaller the aspect ratio of the MOS transistor is configured, the higher the drain-source voltage is required.

By setting it this way, the power supply voltage required for causing the third reference current to flow through the PMOS transistor 32 becomes higher than the power supply voltage required for the first reference current to flow through the PMOS transistor 22. In other words, the minimum operating power supply voltage of the start-up circuit 30 is higher than the minimum operating power supply voltage of the voltage detection circuit 20.

Thus, in the case that the start-up circuit 30 outputs a High level enable signal EN, the voltage detection circuit 20 is in a state of stable operation.

In addition, by setting the aspect ratio of the NMOS transistor 31 slightly larger than that of the NMOS transistor 21, it is also possible to make the minimum operating power supply voltage of the start-up circuit 30 higher than the minimum operating power supply voltage of the voltage detection circuit 20.

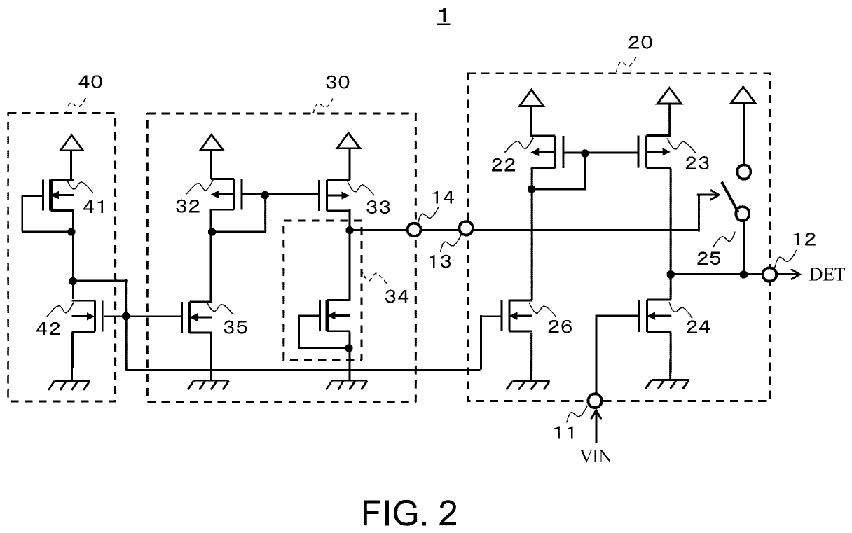

FIG. 2 is a circuit diagram illustrating another example of a voltage detector according to the present embodiment of the present invention.

The voltage detector 1 in FIG. 2 includes a current source circuit 40 in place of the current sources 21 and 31.

The current source circuit 40 includes a depletion-type NMOS transistor 41 serving as a current source, and an enhancement-type NMOS transistor 42 constituting a current mirror circuit.

The voltage detection circuit 20 includes an enhancement-type NMOS transistor 26 that forms a current mirror circuit together with the NMOS transistor 42 which replaces the current source 21. Moreover, the voltage detection circuit 20 is configured to place the switch circuit 25 between the output port 12 and the power supply port. The switch circuit 25 is controlled by the enable signal EN received by to the control port 13, turning on at Low level and off at High level. In other words, in case of below the operating power supply voltage of the voltage detection circuit 20, the output port 12 is pulled up to the power supply voltage.

The start-up circuit 30 includes an enhancement-type NMOS transistor 35 that forms a current mirror circuit together with the NMOS transistor 42 which replaces the current source 31.

The voltage detector 1 in FIG. 2 and the voltage detector 1 in FIG. 1 have similar basic circuit operations, and the relationships between the minimum operating power supply voltage and the voltage detection circuits 20 and the start-up circuits 30 are also similar.

The voltage detector 1 in FIG. 2 is effective as a method to reduce size in cases where the current sources 21 and 31 become large when being designed to satisfy the conditions required in the circuit of FIG. 1.

As described above, according to the voltage detector of the present embodiment, the constant current source of the voltage detection circuit 20 is composed of a depletion-type NMOS transistor and a current mirror circuit, and a start-up circuit 30 is provided for detecting that the power supply voltage becomes equal to or higher than the minimum operating power supply voltage of the voltage detection circuit 20. As a result, the temperature characteristics of the detection voltage are flat while the minimum operating power supply voltage is low, and erroneous detection is prevented below the minimum operating power supply voltage.

The present invention is not limited to the embodiments described above, and may be implemented in various forms. Within the scope of the inventive concept, various omissions, additions, substitutions, or modifications may be made. These embodiments and their modifications are included within the scope and essence of the present invention, as well as within the scope of the present inventions described in the claims and their equivalents.

For example, similar effects can be obtained by interchanging all NMOS transistors and PMOS transistors and inverting the circuit configuration. Additionally, for instance, as long as the switch circuit 25 operates to control the output of the detection signal DET according to the enable signal EN, its position is not limited to those shown in these circuit diagrams. Furthermore, for example, while the current detection circuit 34 was shown to be composed of a depletion-type NMOS transistor with its gate and source connected, it is not limited to this configuration. For instance, the current detection circuit 34 may be composed of a resistor or the like. Moreover, for example, the logic of the signals in the voltage detector 1, the voltage detection circuit 20, and the start-up circuit 30 may be appropriately modified.

What is claimed is:

1. A voltage detector, comprising:
a voltage detection circuit that comprises:
a first current source, with one end connected to a first power supply port and comprising a depletion-type MOS transistor,
a first current mirror circuit, with an input port connected to the other end of the first current source and into which a current of the first current source is input,
an enhancement-type first MOS transistor, with a gate connected to an input port, a drain connected to an output port and an output port of the first current mirror circuit, and into which an output current of the first current mirror circuit is input, and
a switch circuit, controlled by an enable signal received by a control port; and
a start-up circuit that comprises:
a second current source,
a second current mirror circuit, into which a current of the second current source is input, and
a current detection circuit, outputting the enable signal indicating enable in response to detecting that an output current of the second current mirror circuit is input and that the output current has become equal to or greater than a predetermined current,
wherein the voltage detection circuit outputs a detection signal corresponding to a voltage of the input port from the output port in response to receiving the enable signal indicating enable from the start-up circuit at the switch circuit.

2. The voltage detector according to claim 1,
wherein a minimum operating power supply voltage of the start-up circuit is set higher than a minimum operating power supply voltage of the voltage detection circuit.

3. The voltage detector according to claim 2,
wherein the first current mirror circuit outputs a current corresponding to the current of the first current source in response to receiving the enable signal indicating enable at the switch circuit.

4. The voltage detector according to claim 1, comprising a current source circuit having a fourth current source,
wherein the first current source comprises a third current mirror circuit that outputs a current based on a current of the fourth current source, and
the second current source comprises a fourth current mirror circuit that outputs a current based on the current of the fourth current source.

5. The voltage detector according to claim 1, wherein the switch circuit is connected between a source of the first MOS transistor and the first power supply port.

6. The voltage detector according to claim 1, wherein the switch circuit is connected between an output port of the voltage detection circuit and a second power supply port.
